(19) United States
(12) Patent Application Publication
(10) Pub. No.: US 2002/0030979 A1
(43) Pub. Date: Mar. 14, 2002

(54) Circuit board system for optiming contact pin layout in an integrated circuit

(76) Inventor: Nai-Shung Chang, Taipei Hsien (TW)

Correspondence Address: J.C. Patents, Inc., Suite 250, 4 Venture, Irvine, CA, 92618, US

(21) Appl. No.: 09/945,016

(22) Filed: Aug. 30, 2001

(30) Foreign Application Priority Data
Sep. 8, 2000 (TW) 89118401

(51) Int. Cl. H05K 7/02

(52) U.S. Cl. 361/780

(57) ABSTRACT

An integrated circuit pin layout for packaging a chip is provided. A layout for the pins in an integrated circuit package is provided to optimize most of the relative reference voltages or relative reference grounds. The power pins are put together after a definite number is exceeded and neighboring power pins are positioned perpendicular to the edge of the substrate board inside the integrated circuit package. Ultimately, the connection channels of the relative reference voltage layer or the relative power circuit layer (also called the relative reference ground layer) are widened. Consequently, high-frequency impedance of the substrate board is lowered, number of through holes is reduced, number of voltage-stabilizing capacitors is increased and power source is stabilized.

### CROSS-REFERENCE TO RELATED APPLICATION

This application claims the priority benefit of Taiwan application serial no. 89118401, filed Sep. 8, 2000.

### BACKGROUND OF THE INVENTION

1. Field of Invention

The present invention relates to the contact pins of an integrated circuit package. More particularly, the present invention relates to the layout of contact pins in an integrated circuit package.

2. Description of Related Art

Most integrated circuit fabrication starts with a layout design of an integrated circuit chip. According to the layout design, connections between the chip and a substrate are next decided. Locations of the pins on the substrate are subsequently decided followed by the positioning soldering balls during packaging. With this sequence, the soldering points on a printed circuit board (PCB) are also determined by the overall layout design of the pins across the integrated circuit.

However, due to technological breakthroughs, the number of soldering balls needed to connect with an integrated circuit chip continues to rise. Consequently, similar signal pins and power pins are often dissembled. FIG. 1 is a diagram showing a conventional ball out assignment of an integrated circuit package. As shown in FIG. 1, the power pins such as the relative reference voltage (Vcc) and the relative reference ground (Vss) are randomly assigned to various positions on the substrate of the integrated circuit. Furthermore, each relative reference voltage or relative reference ground point must have individual through hole. Hence, the soldering point on the printed circuit board corresponding to the relative reference voltage or relative reference ground point must be drilled. By the way, the other reference signs are not the feature in accordance with the invention, which are cited in the drawing, such as DQS1#, MD12 . . . etc. So that, these reference signs would not be discussed.

To suit the layout of soldering balls on the integrated circuit and to have the inner layer power circuit of the printed circuit board able to use fine but dense lines for connecting to the through-hole positions corresponding to the relative reference voltage or relative reference ground without crossing other relative reference voltage and relative reference ground through holes, high-frequency impedance is often produced.

In most conventional printed circuit board, voltage-regulating capacitors are used to stabilize the voltage output between the relative reference voltage and the relative reference ground. Because the relative reference voltages and the relative reference grounds are so randomly distributed, most printed circuit board must put down extra surface electrical lines for connecting a voltage-stabilizing capacitors between the output terminal of the relative reference voltage and the relative reference ground. Hence, internal connections between the relative reference voltage layer and the relative reference ground layer inside the printed circuit board is at present quite complicated and the number of voltage-stabilizing capacitors that can be put in the bottom layer circuit of the printed circuit board is limited.

Since the printed circuit board must have contact in positions corresponding to the integrated circuit output balls, the number of through holes is increased. Moreover, the fine and intricate channels between the relative reference voltage layer and the relative reference ground layer often lead to high-frequency impedance. In addition, power source instability may occur due to the limited number of voltage-stabilizing capacitors that can be employed. In short, the printed circuit board is fully constrained by the layout of soldering balls on the substrate.

### SUMMARY OF THE INVENTION

Accordingly, one object of the present invention is to provide a contact pin layout for an integrated circuit package. The soldering balls in a conventional integrated circuit are redistributed such that the balls in contact with the relative reference voltage points and the relative reference ground points are more compact and are vertically aligned along the edge of a substrate. In other words, the output terminals of a plurality of identical relative reference voltages or a plurality of identical relative reference grounds in the printed circuit board are connected together so that the same through hole can be used. In addition, the relative reference voltages and the relative reference grounds are connected in such a way that they are aligned in a direction parallel to the signal line. Hence, the channel of the relative reference voltages and the relative reference grounds on the printed circuit board can be wider for connecting with the through holes so that high-frequency impedance is lowered.

It is to be understood that both the foregoing general description and the following detailed description are exemplary, and are intended to provide further explanation of the invention as claimed.

### BRIEF DESCRIPTION OF THE DRAWINGS

The file of this patent contains at least one drawing executed in color. Copies of this patent with color drawing(s) will be provided by the Patent and Trademark Office upon request and payment of the necessary fee.

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram showing a conventional ball out assignment of an integrated circuit package;

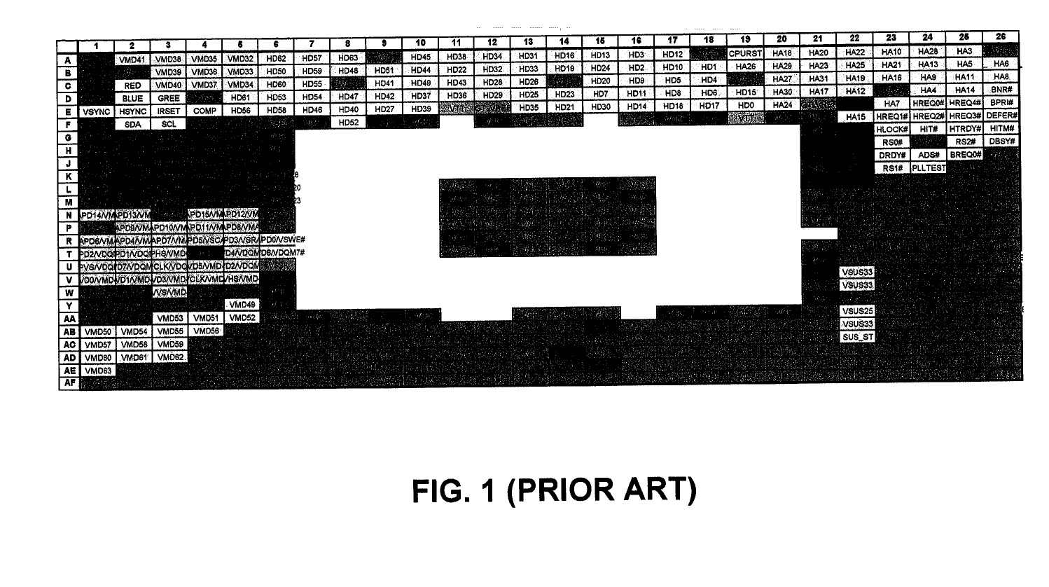

FIG. 2 is a diagram showing a rugged pin assignment in an integrated circuit package according to one preferred embodiment of this invention; and

FIG. 3 is a partially transparent view showing a rugged pin assignment in an integrated circuit according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

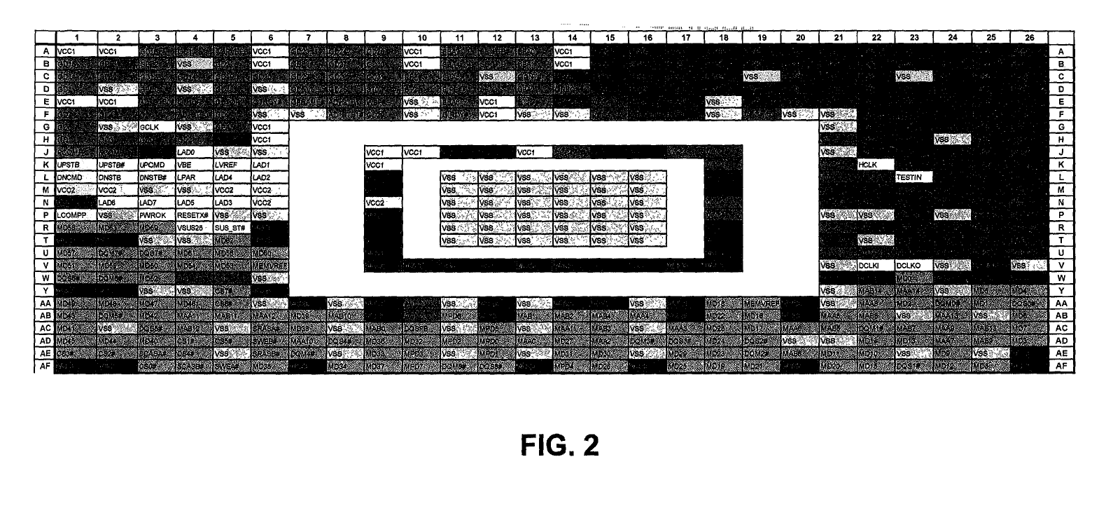

FIG. 2 is a diagram showing a rugged pin assignment in an integrated circuit package according to one preferred embodiment of this invention.

First, a method of fabricating the integrated circuit of this invention is described. The major difference between this invention and a conventional design methodology is to determine soldering ball positions so that most of the relative reference voltage terminals and the relative reference ground terminals, for example, about 5 groups or more of the balls, are densely packed and aligned vertically along the edge of the integrated circuit. According to the ball assignments, contact points on the input/output pads of the substrate and contact points in the integrated circuit are arranged and the internal structure of the integrated circuit are designed accordingly.

Since most of the relative reference voltage terminals or the relative reference ground terminals are densely packed and vertically aligned along the periphery of the integrated circuit, the relative reference voltage layer and the relative reference ground layer of the printed circuit board can use a wider channel. Hence, the high-frequency impedance that results from dense and winding wires of the relative reference voltage layer and relative reference ground layer in a conventional printed circuit board is lowered.

For example, if width of the relative reference voltage layer and the relative reference ground layer in a printed circuit board is 40 mils and high-frequency impedance at 300 MHz is 1Ω (Ohm), current that flows to the printed circuit board circuit of an integrated circuit package is 1 A (Ampere). The printed circuit board circuit has lost 1 V (volt). If the power source is able to provide a 2.5V to the integrated circuit, the actual voltage supplied to the integrated circuit is only 1.5V because 1V is lost by the high-frequency impedance through the integrated circuit.

On the other hand, if the printed circuit board uses a wider channel such that the relative reference voltage layer and the relative reference ground layer has a width of about 100 mils divided into seven channels, the high-frequency impedance will drop to between 0.1 to 0.2 Ohm for an operating frequency of 300 MHz.

Due to the dense packing of the relative reference voltage terminals or the relative reference ground terminals, the relative reference voltage terminals and the relative reference ground terminals that are close to each other can be linked together to form a line parallel to the signal line. Furthermore, a point may be selected to fabricate a through hole, thereby reducing the total number of through holes. Hence, the high-frequency impedance caused by too much through holes in the channel of the relative reference voltage layer and the relative reference ground layer can be prevented.

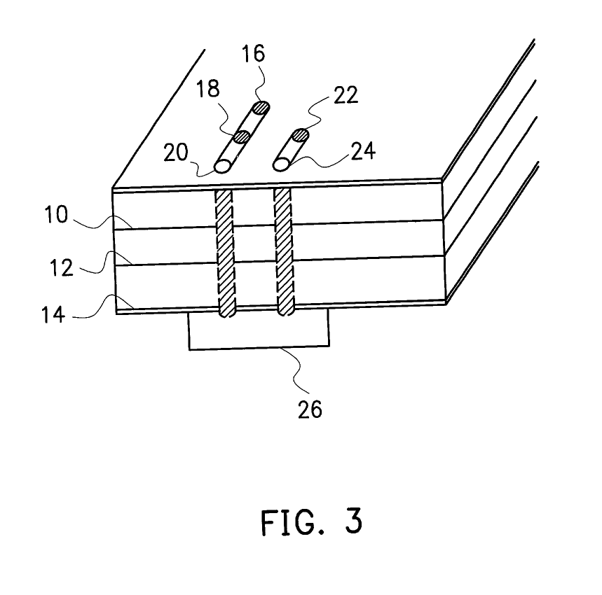

FIG. 3 is a partially transparent view showing a rugged pin assignment in an integrated circuit according to one preferred embodiment of this invention. Because the relative reference voltage terminals or the relative reference ground terminals are aligned vertically along the edge of the integrated circuit and the relative reference voltage soldering point 16/18 and the relative reference ground soldering point 22 are parallel to each other, the number of voltage-stabilizing capacitors 26 can be increased. Hence, input power source can be stabilized. Furthermore, because the through hole 20 and the through hole 24 are next to each other, the bottom layer circuit 14 of the printed circuit board does not require any more linking wires for connecting the relative reference voltage soldering points 16/18 or the relative reference ground soldering point 22 to the voltage stabilizing capacitor 26. In this embodiment, the number of voltage-stabilizing capacitors 26 can be increased to 36.

Most integrated circuit fabrication starts with a layout design of an integrated circuit chip. According to the layout design, connections between the chip and a substrate are next decided. Locations of the pins on the substrate are subsequently decided followed by the positioning soldering balls during packaging. With this sequence, the soldering points on a printed circuit board are also determined by the overall layout design of the pins across the integrated circuit.

However, due to technological breakthroughs, the number of soldering balls needed to connect with an integrated circuit chip continues to rise. Consequently, similar signal pins and power pins are often dissembled. For example, the power pins such as the relative reference voltage and the relative reference ground are randomly assigned to various positions on the substrate of the integrated circuit. Furthermore, each relative reference voltage or relative reference ground point must have individual through hole. Hence, the soldering point on the printed circuit board corresponding to the relative reference voltage or relative reference ground point must be drilled.

To suit the layout of soldering balls on the integrated circuit and to have the inner layer power circuit of the printed circuit board able to use fine but dense lines for connecting to the through-hole positions corresponding to the relative reference voltage or relative reference ground without crossing other relative reference voltage and relative reference ground through holes, high-frequency impedance is often produced.

In most conventional printed circuit board, voltage-regulating capacitors are used to stabilize the voltage output between the relative reference voltage and the relative reference ground. Because the relative reference voltages and the relative reference grounds are so randomly distributed, most printed circuit board must put down extra surface electrical lines for connecting a voltage-stabilizing capacitors between the output terminal of the relative reference voltage and the relative reference ground. Hence, internal connections between the relative reference voltage layer and the relative reference ground layer inside the printed circuit board is at present quite complicated and the number of voltage-stabilizing capacitors that can be put in the bottom layer circuit of the printed circuit board is limited.

Since the printed circuit board must have contact in positions corresponding to the integrated circuit output balls, the number of through holes is increased. Moreover, the fine and intricate channels between the relative reference voltage layer and the relative reference ground layer often lead to high-frequency impedance. In addition, power source instability may occur due to the limited number of voltage-stabilizing capacitors that can be employed. In short, the printed circuit board is fully constrained by the layout of soldering balls on the substrate.

In summary, the present invention provides a contact pin layout for an integrated circuit package. The soldering balls in a conventional integrated circuit are redistributed such that the balls in contact with the relative reference voltage points and the relative reference ground points are more compact and are vertically aligned along the edge of a substrate. The output terminals of a plurality of identical relative reference voltages or a plurality of identical relative reference grounds in the printed circuit board are connected together so that the same through hole can be used. In addition, the relative reference voltages and the relative reference grounds are connected in such a way that they are aligned in a direction parallel to the signal line. Hence, the channel of the relative reference voltages and the relative reference grounds on the printed circuit board can be wider for connecting with the through holes so that high-frequency impedance is lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A contact pin layout for enclosing a chip inside an integrated circuit package, comprising:
a plurality of power pins for providing power to said chip; and
a substrate electrically connected to said power pins and said chip serving as a current channel from said power pins to said chip, wherein power pins that exceed a fix number are grouped next to each other and said direction of alignment of neighboring power pins are perpendicular to said edge of said substrate.

2. The layout of claim 1, wherein said fix number is five power pins.

3. The layout of claim 1, wherein said power pins includes a plurality of soldering balls.

4. A printed circuit board for supporting an integrated circuit having a plurality of power pins, comprising:
a surface circuit having a plurality of first solderspoints, wherein said first soldering points are electrically connected to said power pins with a first potential difference, said first soldering points are next to each other and linked, and said surface circuit serves as a conductive circuit loop;
a first through hole, wherein said first soldering points connect with said only first through hole and said first through hole serves as a conductive circuit loop, and
an internal power circuit having a width greater than or equal to an expected width of a wiring channel, said channel connects with said first through hole, said internal power circuit provides power via said circuit channel, said first through hole and said surface circuit to said integrated circuit.

5. The printed circuit board of claim 4, wherein said surface circuit further includes a plurality of second soldering points, said second soldering points connect electrically with said plurality of power pins at a second potential difference, said printed circuit board also includes:
a second through hole, said second through hole connects with any one of said second soldering points and said second through hole serves as a conductive circuit loop;
a relative power circuit connected with said second through hole; and
a bottom layer circuit having a third soldering point and a fourth soldering point for connecting to a voltage-stabilizing capacitor, said third soldering point connects with a first through hole, said fourth soldering point connects to said second through hole, said first soldering point and said second soldering point are positioned in such as way that distance between said third soldering point and said fourth soldering point fall within said voltage-stabilizing capacitor.

6. The printed circuit board of claim 4, wherein width of said wiring for said internal power circuit is around 100 mils.

7. The printed circuit board of claim 4, wherein said circuit channel of said internal power circuit has a high-frequency impedance of between around 0.1 to 0.2 Ohm at an operating frequency of 300 MHz.

8. A circuit board system, comprising:
an integrated circuit package pin layout, wherein said integrated circuit package encloses a chip, said layout includes:
a plurality of signal pins serving as signal connection channels to said chip;
a plurality of power pins for providing power to said chip; and
a substrate electrically connected to said power pins and said chip serving current channels from said power pins to said chip; and
a printed circuit board for supporting an integrated circuit having a plurality of power pins, wherein said printed circuit board has a surface circuit having a plurality of signal lines each connected to said signal pins, wherein power pins that exceed a fix number are grouped next to each other and said direction of alignment of neighboring power pins are perpendicular to said edge of said substrate.

9. The circuit board system of claim 8, wherein said fix number is five power pins.

10. The circuit board system of claim 8, wherein said signal pins and said power pins include a plurality of soldering balls.

11. The circuit board system of claim 8, wherein said surface circuit of said printed circuit board further includes a plurality of first soldering points, said first soldering points connect with said power pins at a first potential difference, said first soldering points are next to each other and linked, said printed circuit board further includes:
a first through hole, wherein said first soldering points connect with said only first through hole and said first through hole serves as a conductive circuit, and
an internal power circuit having a width greater than or equal to said width of a wiring channel, said channel connects with said first through hole, said internal power circuit provides power via said circuit channel, said first through hole and said surface circuit to said integrated circuit.

12. The circuit board system of claim 11, wherein said surface circuit further includes a plurality of second soldering points, said second soldering points connects electrically with said power pins at a second potential difference, said printed circuit board further includes:
a second through hole, said second through hole connects with any one of said second soldering points and said second through hole serves as a conductive circuit loop;
a relative power circuit connected with said second through hole; and
a bottom layer circuit having a third soldering point and a fourth soldering point for connecting to a voltage-stabilizing capacitor, said third soldering point connects with a first through hole, said fourth soldering point connects to said second through hole, said first soldering point and said second soldering point are positioned in such as way that distance between said third soldering point and said fourth soldering point fall within said voltage-stabilizing capacitor.

13. The printed circuit board of claim 11, wherein width of said wiring for said internal power circuit is around 100 mils.

14. The printed circuit board of claim 11, wherein said circuit channel of said internal power circuit has a high-frequency impedance of between around 0.1 to 0.2 Ohm at an operating frequency of 300 MHz.
